(19) United States
(12) Patent Application Publication
(10) Pub. No.: US 2025/0216456 A1
(43) Pub. Date: Jul. 3, 2025

(54) Chip Self-Repair for Interconnect Short Faults

(71) Applicant: Advanced Micro Devices, Inc., Santa Clara, CA (US)

(72) Inventors: Nehal R. Patel, Sunnyvale, CA (US); Carl Dean Dietz, Columbia City, IN (US); Michael Kevin Ciraula, Fort Collins, CO (US); John J. Wuu, Fort Collins, CO (US); Russell J. Schreiber, Austin, TX (US)

(73) Assignee: Advanced Micro Devices, Inc., Santa Clara, CA (US)

(21) Appl. No.: 18/397,109

(22) Filed: Dec. 27, 2023

(51) Int. Cl. G01R 31/3181; G01R 31/317; G01R 31/319

(52) U.S. Cl. CPC G01R 31/31813; G01R 31/31717; G01R 31/31926

(57) ABSTRACT

A system includes a first chiplet and a second chiplet connected via a plurality of interconnects. The system includes a pattern generator configured to generate a test pattern on behalf of the first chiplet. The system includes a pattern checker configured to check the test pattern on behalf of the second chiplet. The system includes a first repair multiplexer and a second repair multiplexer corresponding to the first chiplet and the second chiplet, respectively. The first repair multiplexer and the second repair multiplexer configured to selectively enable a repair path responsive to a short fault between two interconnects of the plurality interconnects based on the checked test pattern.

### BACKGROUND

Built-In-Self-Test or “BIST” is a technology used in microprocessor chip manufacturing, facilitating integrated circuits to autonomously conduct self-assessments, thereby averting the need to use external test equipment. BIST creates and applies specific test patterns to the chip circuits and subsequently compares the actual output with anticipated outcomes, serving to unveil any disparities or defects in the circuitry. The use cases for BIST extend not only to fault detection but also to safeguarding to ensure that each chip adheres to stringent quality and reliability standards to ensure that defective units are intercepted before reaching consumers. Moreover, BIST equips chips with the capability to undergo self-repair, where mechanisms of the chips may activate to reconfigure the chip to circumvent a fault, such as by disabling a malfunctioning core in a multi-core processor.

### BRIEF DESCRIPTION OF THE DRAWINGS

FIG. 1 depicts a non-limiting example system having a system-on-a-chip or “SoC” including two or more chiplets, an interposer, and a package configurable in multiple configurations.

FIG. 2A depicts a non-limiting example self-repairable chip having multiple lanes and one spare lane across two chiplets.

FIG. 2B depicts the non-limiting example self-repairable chip of FIG. 2A having an open fault between the two chiplets in one lane (lane [0]) and enabling a repair path through a spare lane to bypass the open fault.

FIG. 2C depicts the non-limiting example self-repairable chip of FIG. 2A having a different open fault between the two chiplets in one lane (lane [1]) and engaging a repair path through a spare lane to bypass the open fault.

FIG. 2D depicts the non-limiting example self-repairable chip of FIG. 2A having two short faults between the two chiplets rendering the chip unrepairable using conventional techniques.

FIG. 3 depicts a non-limiting example chiplet interconnect circuit with short faults.

FIGS. 4A and 4B depict an example method for implementing a chip self-repair mechanism to repair interconnect short faults.

FIGS. 5A-5D depict example scenarios of the non-limiting example self-repairable chip of FIG. 2A during implementation of the chip self-repair mechanism described in FIGS. 4A, 4B.

FIGS. 6A-6D depict example scenarios of the non-limiting example self-repairable chip of FIG. 2A after implementation of the chip self-repair mechanism described in FIGS. 4A, 4B.

### DETAILED DESCRIPTION

### Overview

A BIST system generates, manages, and analyzes test patterns, and validates the resultant outcomes in an automated and precise manner. The core functionalities of a BIST system include pattern generation, response analysis, fault identification, classification, and, in some implementations, engaging in self-repair actions, along with maintaining a meticulous log of the testing processes and outcomes. In chip manufacturing, BIST does not merely truncate manufacturing costs by identifying defective chips promptly, curtailing wastage and mitigating the financial impacts of recalls or failed devices, but also accelerates the testing process by providing a rapid and efficient alternative to external testing methodologies. Additionally, BIST ensures persistent reliability by enabling in-field testing and diagnostic operations throughout a chip's lifecycle, thereby elevating the applicability and indispensability of BIST in the semiconductor manufacturing industry.

Interconnect repair in chip manufacturing is a critical process for maintaining the yield and reliability of integrated circuits. In an integrated circuit, the interconnects are essentially the wiring or traces that link together different transistors and other components within the chip, ensuring that the components can communicate and function together as a cohesive unit. Repair mechanisms are crucial because manufacturing defects, such as breaks or short circuits in the interconnect layers, could render a chip nonfunctional or unreliable.

Interconnect repair often necessitates the integration of additional multiplexers or “mux,” within a data path (i.e., a “lane”), with the specific aim to manage spare lanes that serve as alternatives in case the primary lanes encounter faults. Adhering to a linear principle, the implementation of a single spare lane commands the incorporation of one additional mux, while the implementation of two spare lanes demands two additional mux, progressing similarly with the introduction of more spare lanes. However, this insertion of extra mux into high-speed data paths imposes a consequential impact on both speed and overall performance of the chip. Particularly in the context of high-speed interfaces, introducing two or more extra mux into the data path might be impermissible for achieving timing closure (i.e., the process that determines a chip's speed by satisfying timing constraints) due to the potential disruptions in data transmission and processing speed. Moreover, when restricted to the utilization of merely a single spare lane, the recovery from short faults becomes unattainable, given that such faults typically engage two lanes, thus exceeding the remedial capacity of a lone spare lane.

When two interconnects are shorted, the BIST system fails for both lanes. In current chips, since there is only one spare lane available, the chip is not repairable. The disclosed techniques provide a way to recover a chip due to short faults when the chip has one or more repairable lanes. In particular, the disclosed techniques identify a short failure and tri-state a transmitter macro of one of the failing lanes. If the transmitter macro of the other lane is able to transfer the data to the receiver macro of another chiplet, at targeted data rate, the chip is considered repairable. Otherwise, the chip is considered not repairable and is disposed of appropriately.

An example system includes multiple chiplets interconnected via interconnects that form, in part, lanes between the chiplets to enable the exchange of data for processing. Each lane includes a pattern generator and a transmitter macro at one of the chiplets. Each lane also includes a pattern checker and a receiver macro at another one of the chiplets. The pattern generator is configured to produce a distinctive test pattern. The transmitter macro is configured to transmit the test pattern generated by the pattern generator to the receiver macro that passes the test pattern to the pattern checker. The pattern checker is configured to check the test pattern as part of a new BIST process. If the test pattern checked by the pattern checker is different from the test pattern generated by the pattern generator, then a connectivity issue exists in the corresponding lane.

When two lanes are shorted (i.e., two failing lanes), the load on the corresponding interconnects is increased. The transmitter macros are configured with programmable drive strength controls to adjust the drive strength driving the signal carrying the test pattern. The drive strength of the transmitter macro of one of the failing lanes is increased to compensate for this extra load. The transmitter macro of another one of the failing lanes is disabled via a tri-stateable control. The receiver macros are configured with a programmable delay configured to adjust a sampling window during which the test pattern can be received. The programmable delay is used to adjust the sampling window for the receiver macro corresponding to the transmitter macro that is transmitting the signal carrying the test pattern. The receiver macros are also configured with an adjustable termination to disable the receiver macro corresponding to the transmitter macro that is disabled.

A new BIST process is described for chips with one repairable lane. If one repair has been executed, the new BIST process is able to determine if the chip is still repairable or not. In particular, the transmitter macro of one of the failing lanes is disabled. Meanwhile, the drive strength of the transmitter macro of another one of the failing lanes is set to its lowest value. The sampling window of the corresponding receiver macro is set to its left most edge indicative of a lowest delay value. The new BIST process then continues via execution of a sub-routine that increments both the receiver macro sampling window and the transmitter macro drive strength and re-runs the test pattern for a specified number of cycles. If the pattern checker detects exactly one failure (i.e., the test pattern does not match), then the part is repairable. The part is then repaired using on-board self-repair mechanisms, such as part of existing BIST processes. Otherwise, the sub-routine checks whether maximum values have been reached for the drive strength and the sampling window. If so, the sub-routine is repeated for the other failing lane. If the corresponding pattern checker detects exactly one failure, then the part is repairable. The part is then repaired using on-board self-repair mechanisms, such as part of existing BIST processes. Otherwise, the part is not repairable. Parts that are not repairable are disposed of appropriately.

The described techniques enhance chip recovery by using existing BIST solutions, negating the need for additional hardware. If a chiplet can handle multiple repairs, it is possible to address a short fault alongside another type, such as an open fault affecting a single lane. With the increasing demands on performance, chiplet interfaces often operate at multi-gigahertz frequencies. In this environment, utilizing more than one repair multiplexer may not be feasible for advanced system-on-a-chip (SoC) designs. The disclosed techniques provide a practical approach, enabling recovery of short faults with one or more repair lanes.

In some aspects, the techniques described herein relate to a system including: a first chiplet connected to a second chiplet via a plurality of interconnects, and one or more repair multiplexers configured to selectively enable a repair path responsive to a short fault between two interconnects of the plurality of interconnects based on a checked test pattern.

In some aspects, the techniques described herein relate to a system, wherein a test pattern is generated on behalf of the first chiplet, and wherein the test pattern is checked on behalf of the second chiplet.

In some aspects, the techniques described herein relate to a system, wherein the second chiplet is configured to indicate a checker fail responsive to the test pattern being different from the test pattern generated on behalf of the first chiplet.

In some aspects, the techniques described herein relate to a system, wherein the checker fail occurs after one repair of an additional short fault between the two interconnects of the plurality of interconnects.

In some aspects, the techniques described herein relate to a system, further including: an interposer including the plurality of interconnects connecting a plurality of chiplets including the first chiplet and the second chiplet, and a package including the plurality of chiplets, and the interposer.

In some aspects, the techniques described herein relate to a chiplet including: a transmitter macro circuit configured to transmit a first test pattern to an additional chiplet during a self-test, a receiver macro circuit configured to receive a second test pattern from the additional chiplet during the self-test, a drive strength control mechanism configured to control a drive strength value of the transmitter macro circuit during transmission of the first test pattern to the additional chiplet to compensate for an additional load created by a short fault between the chiplet and the additional chiplet, and a programmable delay mechanism configured to adjust a sampling window of the receiver macro circuit during reception of the second test pattern from the additional chiplet, the second test pattern interpreted as received to indicate a viability of using a repair path to bypass the short fault between the chiplet and the additional chiplet.

In some aspects, the techniques described herein relate to a chiplet, further including a plurality of interconnects connecting the chiplet to the additional chiplet, and wherein the transmitter macro circuit is connected to a further receiver macro circuit of the additional chiplet via an interconnect of the plurality of interconnects.

In some aspects, the techniques described herein relate to a chiplet, wherein the short fault is caused by the interconnect being shorted with an additional interconnect of the plurality of interconnects.

In some aspects, the techniques described herein relate to a chiplet, wherein the transmitter macro circuit is configured to receive an output enable signal responsive to the interconnect being shorted with the additional interconnect of the plurality of interconnects.

In some aspects, the techniques described herein relate to a chiplet, wherein: responsive to the output enable signal being set to one, the drive strength control mechanism is configured to set the drive strength value to a minimum value, or responsive to the output enable signal being set to zero, the transmitter macro circuit is configured to be tri-stated to disable output from the transmitter macro circuit.

In some aspects, the techniques described herein relate to a method including: responsive to detecting two failing lanes between a first chiplet and a second chiplet of a chip as a result of a short fault, deactivating a transmitter macro circuit of a first failing lane of the two failing lanes to isolate a second failing lane of the two failing lanes, reducing a drive strength of a transmitter macro circuit of the second failing lane, the reduced drive strength used to transmit a signal including a test pattern to a receiver macro circuit of the second failing lane, adjusting a sampling window of the receiver macro circuit of the second failing lane, the adjusted sampling window used to receive the transmitted signal, and executing a sub-routine to determine whether the test pattern is received correctly in the adjusted sampling window by the receiver macro circuit of the second failing lane, an output of the sub-routine indicating whether or not the chip is repairable based on a number of times the test pattern is received correctly.

In some aspects, the techniques described herein relate to a method, wherein the short fault is between a first interconnect in the first failing lane and a second interconnect in the second failing lane.

In some aspects, the techniques described herein relate to a method, wherein the first failing lane and the second failing lane are adjacent to each other.

In some aspects, the techniques described herein relate to a method, wherein the first failing lane and the second failing lane are neighboring a third lane.

In some aspects, the techniques described herein relate to a method, wherein the chip includes a system-on-a-chip.

In some aspects, the techniques described herein relate to a method, wherein executing the sub-routine includes incrementing the sampling window of the second receiver macro circuit of the second failing lane, incrementing the drive strength of the second transmitter macro circuit of the second failing lane, and transmitting, by the second transmitter macro circuit, for a number of cycles, a pattern generated by the first chiplet to the second chiplet.

In some aspects, the techniques described herein relate to a method, wherein executing the sub-routine further includes, responsive to the second chiplet identifying one checker failure, providing the output indicating that the chip is repairable.

In some aspects, the techniques described herein relate to a method, wherein executing the sub-routine further includes, responsive to the second chiplet identifying two checker failures, maximizing the drive strength of the second transmitter macro circuit, and maximizing the sampling window of the second receiver macro: deactivating the second transmitter macro of the second failing lane of the two failing lanes, minimizing a drive strength value of the first transmitter macro of the first failing lane of the two failing lanes, adjusting a sampling window of a first receiver macro of the first failing lane, and re-executing the sub-routine, the output of which indicates whether or not the chip is repairable.

In some aspects, the techniques described herein relate to a method, wherein, responsive to the output of re-executing the sub-routine indicating one checker failure, providing the output indicating that the chip is repairable.

In some aspects, the techniques described herein relate to a method, wherein, responsive to the output of re-executing the sub-routine identifying two checker failures, maximizing the drive strength value of the first transmitter macro circuit, and maximizing the sampling window of the first receiver macro circuit, providing the output indicating that the chip is not repairable.

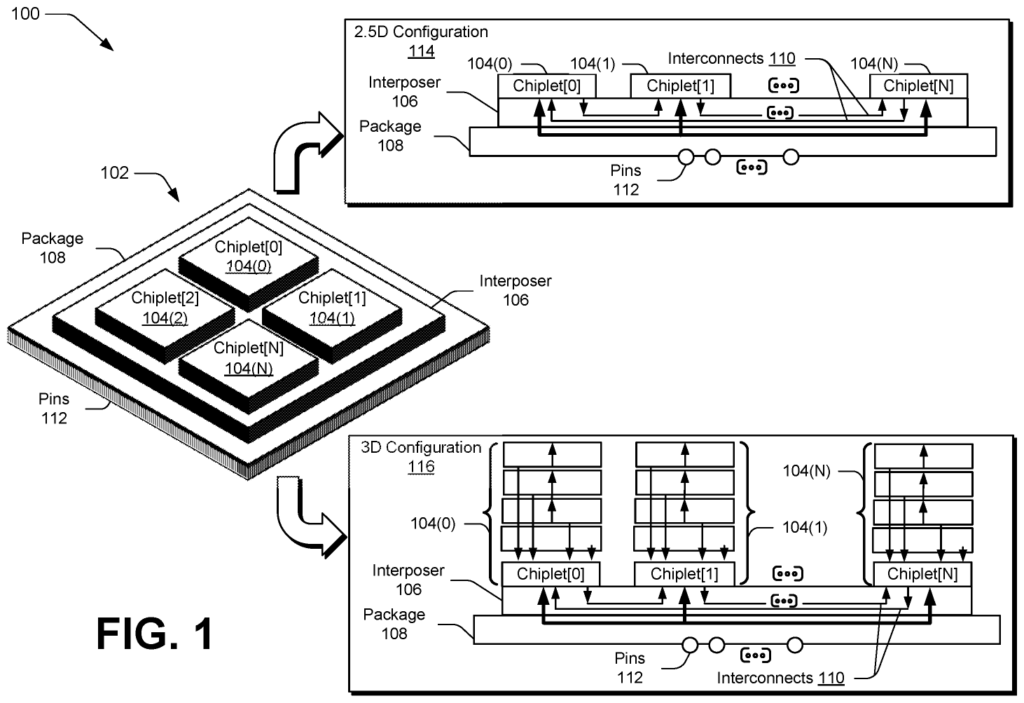

FIG. 1 depicts a non-limiting example system 100 having a SoC 102 including a plurality of chiplets 104(0)-104(N), an interposer 106, and a package 108. The SoC 102 is an electronic circuit that performs various operations on and/or using data, such as data stored in a memory (not shown). Examples of the SoC 102 include, but are not limited to, a central processing unit (CPU), a graphics processing unit (GPU), a field programmable gate array (FPGA), an accelerated processing unit (APU), and a digital signal processor (DSP), to name a few. For example, in one or more implementations, the SoC 102 is a processing unit that reads and executes instructions (e.g., of a program), examples of which include to add, move, branch, or otherwise manipulate data and/or perform various operations using the data.

The chiplets 104 are modular and reusable components of the SoC 102, designed to perform a specific function or set of functions within the SoC 102. Unlike a monolithic chip, where all components (e.g., CPU cores, memory, I/O, etc.) are integrated onto a single piece of silicon, in a chiplet-based design, each function or group of functions is fabricated as a separate, smaller chip embodied as a chiplet 104. The individual chiplets 104 are then interconnected via interconnects 110, through the interposer 106, and designed on top of the package 108 substrate to create a fully functional semiconductor device (also referred to herein as a “chip”).

The interposer 106 acts as a middle layer, providing dense data routing capabilities and enabling high-bandwidth connections, via the interconnects 110, between the chiplets 104. This structure significantly enhances performance, especially for chiplets 104 that need to work in tandem.

The chiplets 104 and the interposer 106 are encapsulated within the package 108. The package 108 not only provides physical protection but also facilitates electrical connections, through pins 112 and/or solder balls, depending on the packaging technology.

The illustrated example shows two possible example configurations of the SoC 102, including a two-and-a-half-dimensional or 2.5D configuration 114 and a three-dimensional configuration or 3D configuration 116. In the 2.5D configuration 114, the chiplets 104 and the interposer 106 lie side-by-side on the same horizontal plane. In one or more implementations, the chiplets 104 and the interposer 106 are interconnected by the interconnects 110, such as using Through-Silicon Vias (TSVs) and/or micro-bumps. While the chiplets 104 are not stacked directly on top of each other, the chiplets 104 are densely packed, and therefore are referred to as being in the 2.5D configuration 114. The entire ensemble is then mounted onto the package 108 substrate, which connects the system 100 to external environments through the pins 112.

On the other hand, the 3D configuration 116 shows a vertical stacking of the chiplets 104 (or groups of chiplets 104). Here, one chiplet 104 is placed directly on top of another chiplet 104, with the interposer 106 potentially at the bottom (as shown) or sandwiched between the chiplets 104. This design maximizes the use of vertical space and reduces the distance, and hence, the latency, between different chiplets 104. The interconnects 110, e.g., embodied as TSVs, provide the electrical connections through the depth of the stacked chiplets 104.

Although two configurations are shown, the SoC 102 is configurable in other configurations such as 3.5D. As such, the configurations illustrated and described herein should not be construed as being limiting in any way.

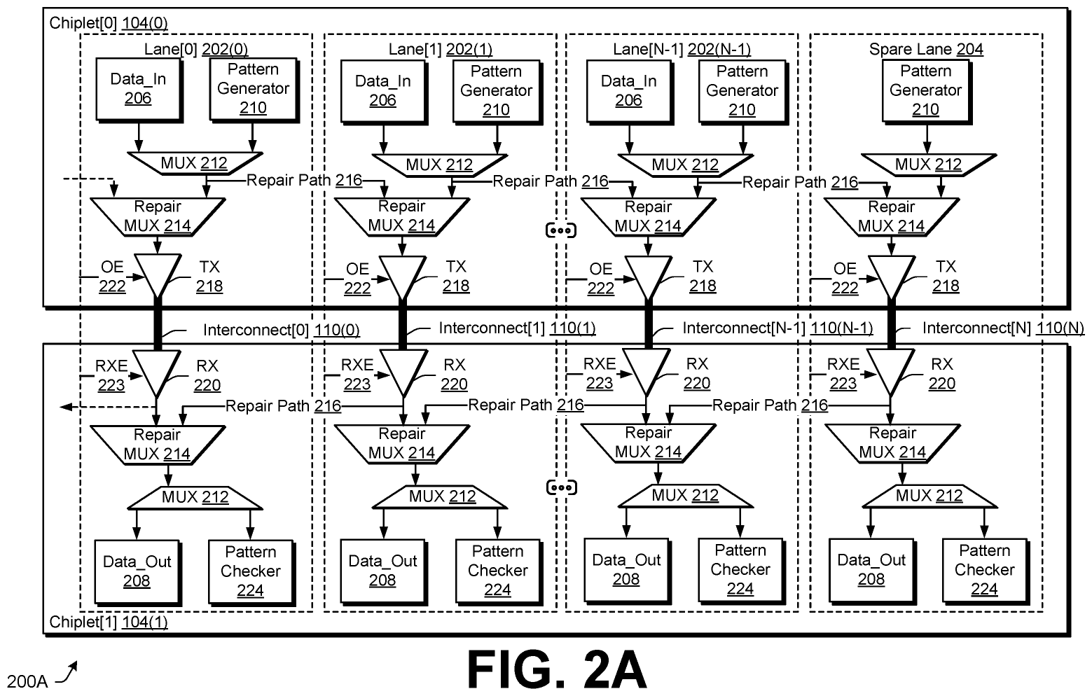

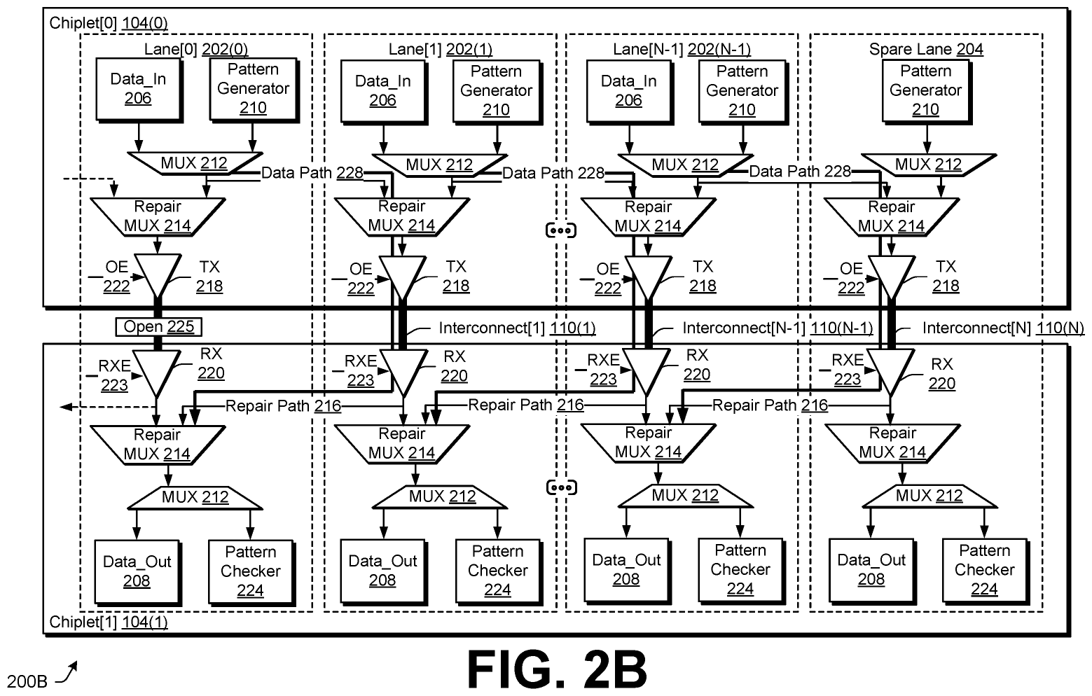

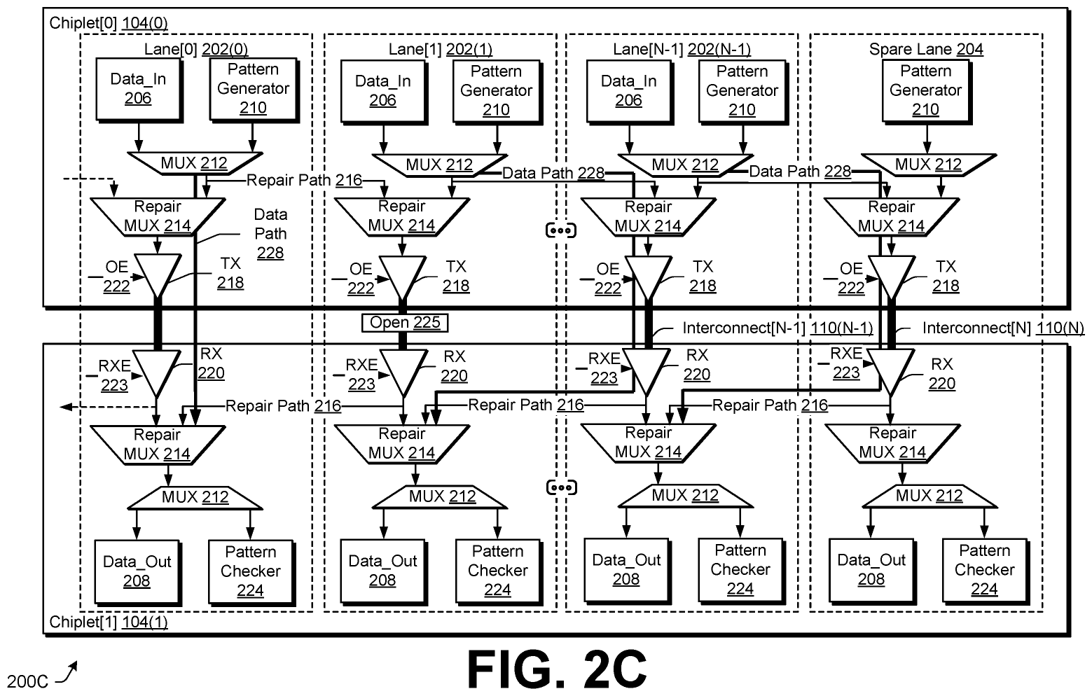

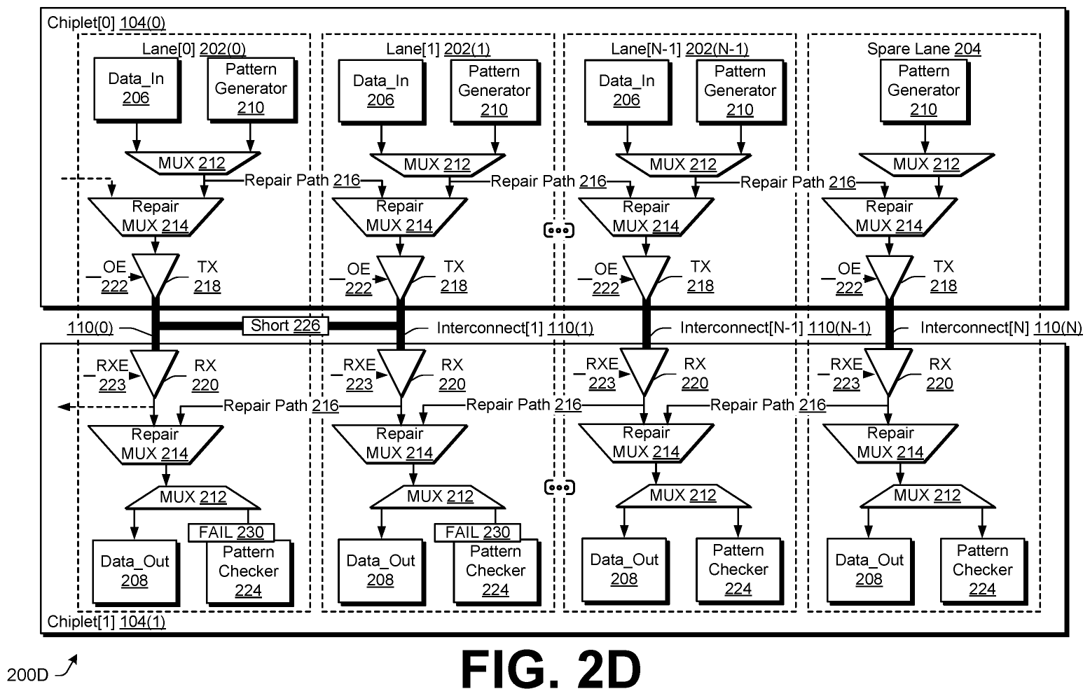

FIG. 2A depicts a non-limiting example self-repairable chip 200A, such as the SoC 102, having multiple lanes 202(0)-202(N-1) and one spare lane 204 across two chiplets 104(0), 104(1). The lanes 202 are paths or channels through which data is transmitted or received within the self-repairable chip 200A. The lanes 202 handle the transmission or reception of data. The spare lane 204 is an additional, redundant lane that is incorporated into the design of the self-repairable chip 200A but is not actively used during normal operation. The spare lane 204 is a backup and enables the self-repair mechanism of the self-repairable chip 200A.

In the context of BIST and testing, if a particular lane, such as the lane [0] 202(0) is detected as defective or not meeting performance requirements during testing, the self-repairable chip 200A is reconfigured to replace the lane [0] 202(0) with the spare lane 204. This redundancy ensures that the self-repairable chip 200A can still function at full capacity even if there are defects or issues with one of the lanes 202.

Each lane 202 includes data input 206(shown as “data_in”) representative of data entering a macro circuit (e.g., from memory and/or from on-die logic) and data output 208 (shown as “data_out”) representative of data leaving the macro circuit (e.g., to memory, on-die logic, or to an I/O device). In the illustrated example, the data input 206 is processed by the chiplet [0] 104(0) and sent via the interconnect [0] 110(0) for further processing by the chiplet [1] 104(1) before being sent out as the data output 208.

In the illustrated example, each lane 202 also includes a pattern generator 210 shown in the chiplet [0] 104(0). The pattern generator 210 is responsible for producing a sequence of test patterns (e.g., input vectors) that are applied to the circuit-under-test (CUT) within the self-repairable chip 200A as part of a self-test. The pattern generator 210 is used to stimulate the CUT in such a way that potential faults, such as open, short faults, can be exposed. There are different strategies and algorithms for generating these test patterns, with the goal of achieving high fault coverage in minimal time. For example, in one or more implementations, the pattern generator 210 is implemented as one or more circuits, such as a pseudorandom pattern generator using Linear Feedback Shift Registers (LFSRs) to produce a sequence of patterns that, while not truly random, cover a wide range of possibilities. This approach is capable of detecting many faults but might not be optimized for specific known potential issues. As another example, in one or more implementations, the pattern generator 210 is implemented as one or more circuits, such as a deterministic pattern generator that produces predefined sequences designed to target specific known potential faults or problem areas in the CUT. The pattern generator 210 is not limited to any specific strategy or algorithm for generating test patterns. Accordingly, the example strategies and algorithms described above should not be construed as being limiting in any way.

The data input 206 and the pattern generator 210 are input to a MUX 212, which is a combinational circuit that takes multiple input signals (i.e., the data input 206 and a pattern generated by the pattern generator 210) and, based on a control signal, selects one of the signals to be the output. In the context of a repair circuit, the MUX 212 outputs to a redundant MUX shown as a repair MUX 214 that is designed to re-route signals via a repair path 216 or select between a functional block and its redundant counterpart in an adjacent lane.

Output of the repair MUX 214 is provided to a transmitter or transmitter macro 218. The transmitter macro 218 handles transmission of data, such as the data input 206 and/or a pattern generated by the pattern generator 210, from the chiplet [0] 104(0), over the interconnect 110, to a receiver or receiver macro 220 of the chiplet [1] 104(1). The transmitter macro 218 is controlled by an output enable or OE signal 222. The receiver macro 220 is controlled by an RX enable or RXE signal 223.

In one or more implementations, the transmitter macro 218 and the receiver macro 220 are pre-designed, reusable circuits that perform a specific function or set of functions (e.g., transmitter for transmission functions and receiver for reception functions). Instead of designing certain functionalities from scratch every time, designers can re-use the transmitter macro 218 and the receiver macro 220 to expedite the design process and ensure that each chiplet 104 is using a tested and proven circuit design.

For the transmitter macro 218, the OE signal 222 determines if the transmitter macro 218 should drive its output onto the interconnect 110. When the OE signal 222 is active (typically HIGH), the transmitter macro 218 will drive its output. When the OE signal 222 is inactive (typically LOW), the transmitter macro 218 will be in a high-impedance state (or “tri-state”), effectively disconnecting the transmitter macro 218 from the interconnect 110. In BIST scenarios, specifically, the transmitter macro 218 is used to selectively enable or disable transmission of tests patterns (e.g., generated by the pattern generator 210) to the CUT.

For the receiver macro 220, when the RX enable signal 223 is active, the receiver macro 220 forwards or drives its output. When the RX enable signal 223 is inactive, the receiver macro 220 suppresses its output. In BIST scenarios, specifically, the receiver macro 220 controls the flow of received data, especially if there is a need to isolate the received test responses from subsequent stages or components during testing.

Output of the receiver macro 220 is provided to a repair MUX 214 which outputs to a MUX 212. The MUX 212 outputs the data output 208 in normal operation and the test pattern to a pattern checker 224 during testing. The pattern checker 224 evaluates the output of the MUX 212 against expected results. If discrepancies arise, the pattern checker 224 indicates that a potential fault exists in the CUT.

The pattern checker 224, in one or more implementations, is a circuit, such as a signature analyzer that, instead of storing all expected outputs, the outputs over a test sequence are compressed into a signature using hardware (e.g., a LFSR). At the end of a self-test, the generated signature is compared to a precomputed, expected signature. If the signatures match, the test is considered passed; otherwise, a fault is indicated. The pattern checker 224, in one or more alternative implementations, is circuit, such as a mismatch detector that directly compares the output of the CUT with an expected output for every test pattern. A mismatch detector uses knowledge of the expected response for each input.

The overall architecture of the self-repairable chip 200A is unchanged in FIGS. 2B and 2C. In FIG. 2B, a non-limiting example self-repairable chip 200B is shown having an open fault 225 (or any other kind of fault, such as stuck-at-0, stuck-at-1, which involve only one lane) in the interconnect [0] 110(0) between the two chiplets 104(0), 104(1) in the lane [0] 104(0). As a result of the open fault 225, the self-repairable chip 200B engages the repair path 216 as a data path 228 to bypass the lane [0] 104(0) and instead use the spare lane 204 to repair connectivity between the chiplets 104(0), 104(1).

Similarly, in FIG. 2C, a non-limiting example self-repairable chip 200C is shown having an open fault 225 in the interconnect [1] 104(1) between the two chiplets 104(0), 104(1) in the lane [1] 104(1). As a result of the short fault 226, the self-repairable chip 200C engages the repair path 216 as a data path 228 to bypass the lane [1] 104(1) and instead use the spare lane 204 to repair connectivity between the chiplets 104(0), 104(1). It should be noted that the data path 228 between the chiplets 104(0), 104(1) in the lane [0] 104(0) remains unchanged in this example.

FIG. 2D depicts a non-limiting example self-repairable chip 200D having short faults 226 between the two chiplets 104(0), 104(1) on the lane [0] 104(0) and the lane [1] 104(1) resulting in a checker fail 230 (“FAIL”) output by the pattern checker 224. The non-limiting example self-repairable chip 200D is not repairable using conventional techniques.

The described techniques identify a short fault 226 and tri-state (i.e., high impedance) a transmitter macro 218 of a failed lane, e.g., lane [0] 110(0). If a transmitter macro 218 of another failed lane, e.g., lane [1] 110(1), is able to transfer data to another chiplet, e.g., from the chiplet 104(0) to the chiplet 104(1), the chip is repairable. When two lanes 202 are shorted, the load on the interconnect 110 is increased as compared to a point-to-point wire connection. To compensate for the extra load, the transmitter macro 218 increases its drive strength. This increase in drive strength creates distortion which can affect data integrity. Accordingly, implementations of the transmitter macros 218 and the receiver macros 220 in accordance with the described techniques have the following capabilities.

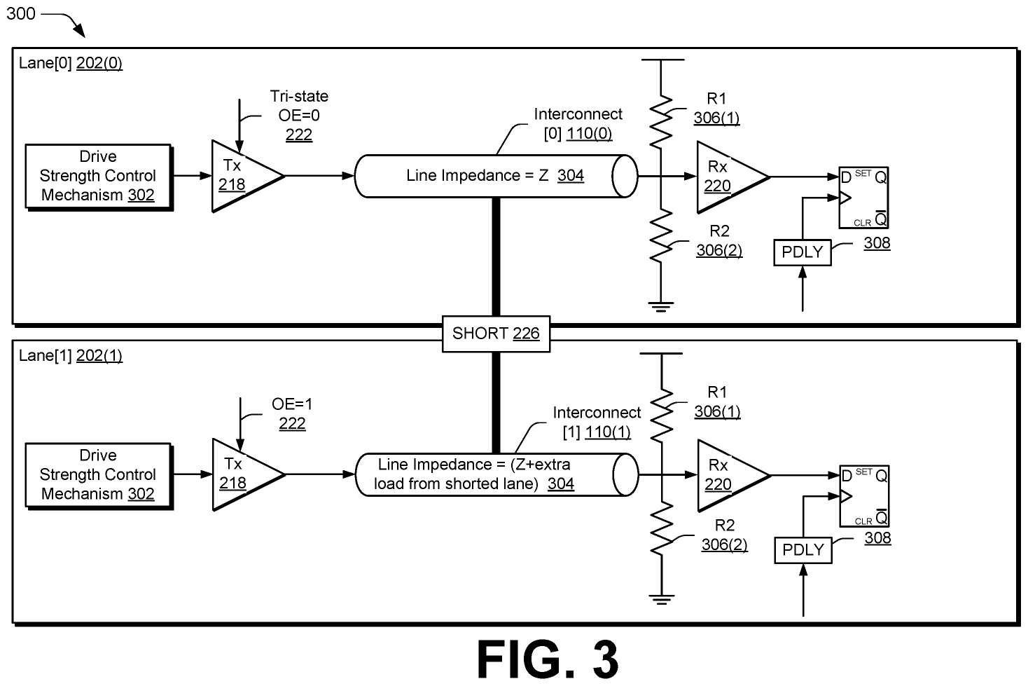

The transmitter macros 218 have a programmable drive strength control (shown in FIG. 3) that is used for the transmitter macro 218 that is driving a signal. The transmitter macros 218 also have a tri-stateable control that is used for the transmitter macro 218 that will not be in use and is disabled. The receiver macros 220 include an adjustable sampling time window that is used for the receiver macro 220 that is receiving the signal. The receiver macros 220 also have adjustable termination used for terminating a disabled lane.

FIG. 3 depicts a non-limiting example chiplet interconnect circuit 300 between the chiplets 104(0), 104(1). The interconnect circuit 300 includes one transmitter macro 218 and one receiver macro 220 for each of the lanes 202(0), 202(1). In the illustrated example, the transmitter macros 218 are equipped with a drive strength control mechanism 302 that allows for the adjustment of drive strength. The drive strength is a measure of the current and voltage capabilities of the transmitter macro 218. The drive strength control mechanism 302 is used to increase or decrease the drive strength to balance signal integrity, manage power consumption, and mitigate potential electromagnetic interference. Additionally, the transmitter macros 218 are configured to enter a tri-state mode when prompted by the OE signal 222, specifically when the OE signal 222 is set to a value of 0 (i.e., OE=0).

The receiver macros 220 are designed with a feature that allows for adjustable impedance control. This adjustability is used for matching the impedance of the receiver macros 220 to a line impedance 304, ensuring optimal signal integrity and minimizing interference. Two resistors, R1 306(1) and R2 306(2), are illustrated to enable this adjustment. The values of the resisters 306 are tweaked to ensure that signal reflections within the line are minimized or eliminated. Reflections degrade signal quality, so eliminating reflections is preferable. Additionally, the receiver macros 220 incorporate a programmable clock delay or PDLY 308. The PDLY 308 is adjustable to set an optimal sampling window, ensuring that the receiver macros 220 sample the incoming signal at the time most suitable for accurate data interpretation.

In scenarios where two interconnects 110 experience a short fault 226, a particular protocol is followed to maintain signal integrity. Specifically, one of the transmitter macros 218 linked to these interconnects 110 is put into a tri-state mode (i.e., OE=0), effectively disabling its output. This is a protective measure to prevent signal conflicts and potential damage. When such a short fault 226 occurs, it effectively creates an additional load on the signal line due to the merged pathways. This extra load alters the line impedance 304 characteristics. For example, as shown, the line impedance 304 in the lane [0] 202(0) is equal to “Z,” and the line impedance 304 in the lane [1] 202(1) is equal to “Z+extra load from the shorted lane”. As a countermeasure, the values of the resistors R1 306(1) and R2 306(2) are readjusted. The aim is, once again, to ensure minimal to no reflection in the signal line, even with the added load caused by the short fault 226. Proper adjustment ensures that the integrity of the signal is maintained, and data transmission remains accurate.

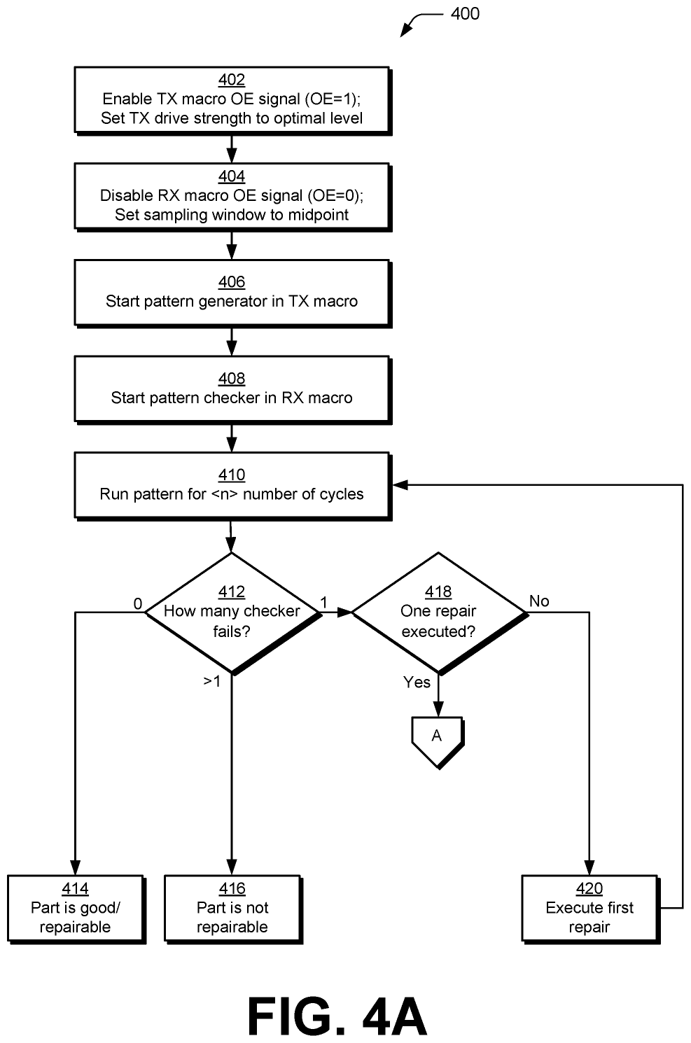

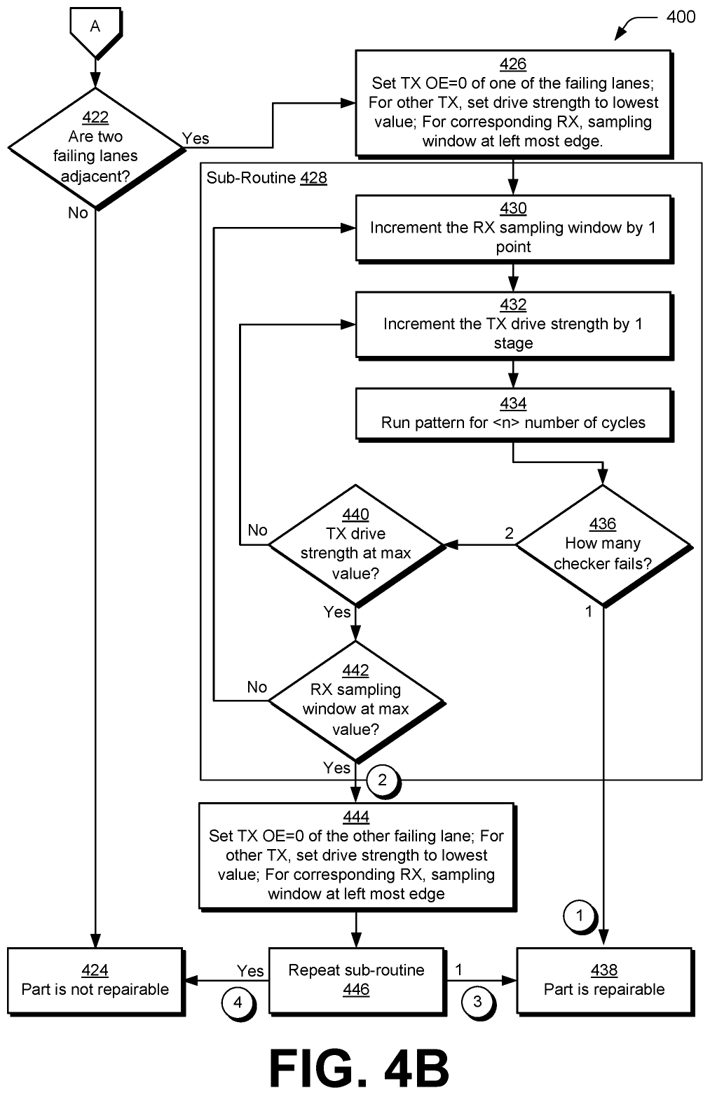

FIGS. 4A-4B depict a method 400 for implementing a chip self-repair mechanism to repair interconnect short faults. The order in which the method 400 is described is not intended to be construed as a limitation, and any number or combination of the described method operations may be performed in any order to perform a method, or an alternate method.

At block 402, an OE signal 222 of a transmitter macro 218 is enabled (i.e., OE=1) to allow the transmitter macro 218 to actively transmit signals. For example, as shown in FIG. 3, the OE signal 222 into the transmitter macro 218 of the chiplet [1] 104(1) is set equal to 1. Also at block 402, the transmitter drive strength is set to an optimal level via the drive strength control mechanism 302. This ensures that the transmitted signals maintain good signal integrity across the transmission line, balancing robustness with power consumption.

At block 404, an RX enable signal 223 of a receiver macro 220 is disabled (i.e., RXE-0) to prepare the receiver macro 220 to receive signals without actively driving its own outputs. For example, as shown in FIG. 3, the RX enable signal 223 into the receiver macro 220 of the chiplet [0] 104(0) is set equal to 0. Also at block 404, a sampling window of the receiver macro 220 is set to its midpoint. For example, as shown in FIG. 3, a PDLY 308 is used to adjust the sampling window to ensure that the receiver macro 220 samples incoming signals at the most appropriate and accurate point in time, maximizing the chances of correct data interpretation.

At block 406, a pattern generator 210 is initiated. This causes the transmitter macro 218 to begin transmitting a predefined pattern or sequence of signals, which can be used for testing or synchronization purposes. At block 408, a pattern checker 224 is initiated. As the transmitter macro 218 transmits the pattern generated by the pattern generator 210, the pattern checker 224 evaluates the received signals against an expected pattern. This helps verify integrity of the transmission at targeted clock frequency, and the proper functioning of both macros.

At block 410, the transmitter macro 218 continues transmitting the pattern for a specific duration, denoted as <n> number of cycles. This ensures a comprehensive test over a set period, enabling the receiver macro 220 to evaluate the transmission consistency and accuracy across multiple cycles.

At block 412, the pattern checker 224 determines how many times the transmitted pattern does not match the received pattern for all lanes (i.e., how many checker fails). If the transmitted pattern consistently matches the received pattern for all lanes (i.e., “0” checker fails), the part, e.g., the SoC 102, is considered “good” (block 414). If the transmitted pattern does not match the received pattern for more than one lane (i.e., “>1” checker fails), the part, e.g., the SoC 102, is considered “not repairable” (block 416). If the transmitted pattern does not match the received pattern for only one lane (i.e., exactly “1” checker fail), the pattern checker 224 determines if one repair has been executed (block 418). If not, a first repair is executed and the data path 228 is shifted right via the repair MUX 214(block 420), after which the pattern checker 224 continues running the pattern (block 410). If only one lane failing and one repair has already been executed, the part, e.g., the SoC 102, determines if the two failing lanes 202 are adjacent (block 422 in FIG. 4B). An example of this scenario is depicted in FIG. 2D.

If the two failing lanes 202 are not adjacent, the part, e.g., the SoC 102, is considered “not repairable” (block 424). If the two failing lanes 202 are adjacent, the part, e.g., the SoC 102, performs additional operations to determine whether or not it is repairable. At block 426, for one of the failing lanes 202, the OE signal 222 for the transmitter macro 218 is deactivated (i.e., OE=0). This ensures that the transmitter macro 218 of the corresponding failing lane 202 remains inactive and does not forward any signals. Simultaneously, at block 426, the drive strength of the other transmitter macro 218 is minimized via the drive strength control mechanism 302. The drive strength is an indication of how powerfully a signal is sent from the transmitter macro 218, and in this operation, the drive strength is set to the weakest setting. Also at block 426, for the corresponding receiver macro 220 in the failing lane 202, the sampling window is adjusted to the left most edge via the PDLY 308.

A sub-routine 428 is then executed. At block 430 of the sub-routine 428, the sampling window of the receiver macro 220 is incremented by “1” point towards the right, ensuring a slight delay in when the receiver macro 220 begins listening. At block 432 of the sub-routine 428, the drive strength of the transmitter macro 218 is increased incrementally by “1” stage via the drive strength control mechanism 302.

At block 434 of the sub-routine 428, the transmitter macro 218 transmits the pattern for a specific duration, denoted as <n> number of cycles, similar to the operation at block 410 described above. This ensures a comprehensive test over a set period, enabling the receiver macro 220 to evaluate the transmission consistency and accuracy across multiple cycles.

At block 436 of the sub-routine 428, the pattern checker 224 determines how many times the transmitted pattern does not match the received pattern for all lanes (i.e., how many checker fails). If the transmitted pattern matches the received pattern for only one lane (i.e., “1” checker fail), the part, e.g., the SoC 102, is considered “repairable” (block 438).

If, instead, the transmitted pattern does not match the received pattern for two lanes (i.e., “2” checker fails), the drive strength control mechanism 302 determines if the drive strength of the transmitter macro 218 at the maximum value (block 440). If the drive strength of the transmitter macro 218 is not at the maximum value, the drive strength of the transmitter macro 218 is increased incrementally by “1” stage via the drive strength control mechanism 302(block 432) and the sub-routine 428 continues as described above. If the drive strength of the transmitter macro 218 is at the maximum value, the PDLY 308 determines if the sampling window of the receiver macro 220 is at the maximum value (block 442). If the sampling window of the receiver macro 220 is not at the maximum value, the sampling window of the receiver macro 220 is incremented by “1” point towards the right (block 430) and the sub-routine 428 continues as described above. If the sampling window of the receiver macro 220 is at the maximum value, the sub-routine 428 ends.

At block 444, for the other one of the failing lanes 202, the OE signal 222 for the transmitter macro 218 is deactivated (i.e., OE=0). This ensures that the transmitter macro 218 of the corresponding failing lane 202 remains inactive and does not forward any signals. Simultaneously, at block 444, the drive strength of the other transmitter macro 218 is minimized via the drive strength control mechanism 302. The drive strength is an indication of how powerfully a signal is sent from the transmitter macro 218, and in this operation, the drive strength is set to the weakest setting. Also at block 444, for the corresponding receiver macro 220 in the failing lane 202, the sampling window is adjusted to the left most edge via the PDLY 308.

At block 446, the sub-routine 428 is repeated. As described above, the output of the sub-routine 428 is either “1” from block 436 or “Yes” from block 442. If the output of the sub-routine 428 is “1,” the part, e.g., the SoC 102, is considered “repairable” (block 438). If the output of the sub-routine 428 is “Yes,” the part, e.g., the SoC 102, is considered “not repairable” (block 424).

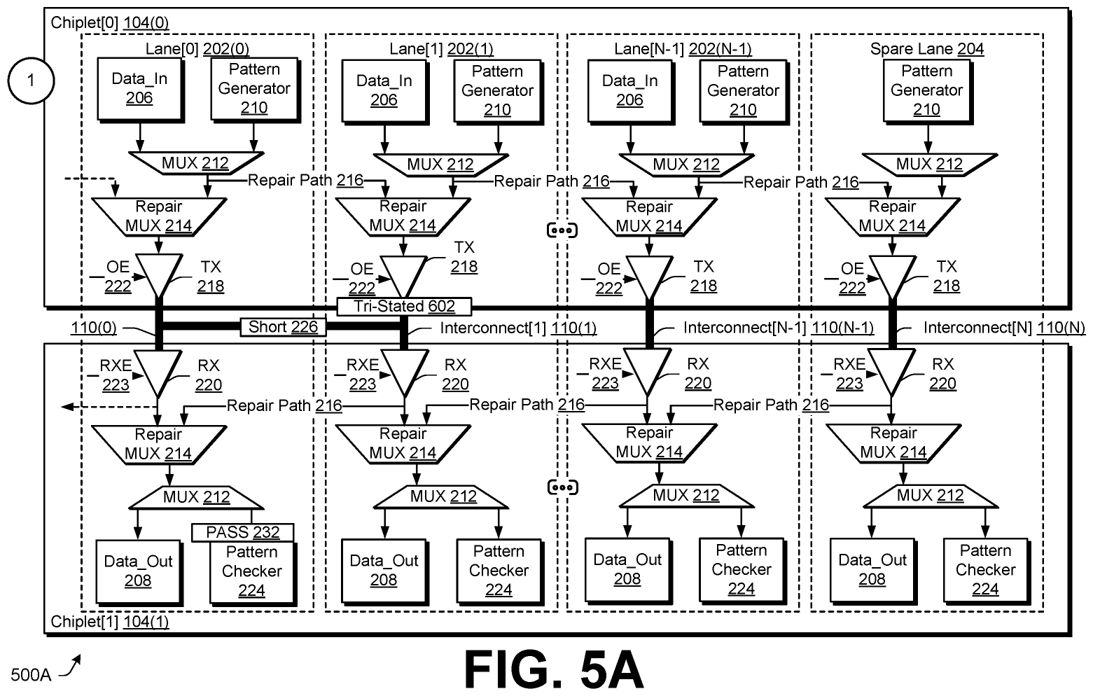

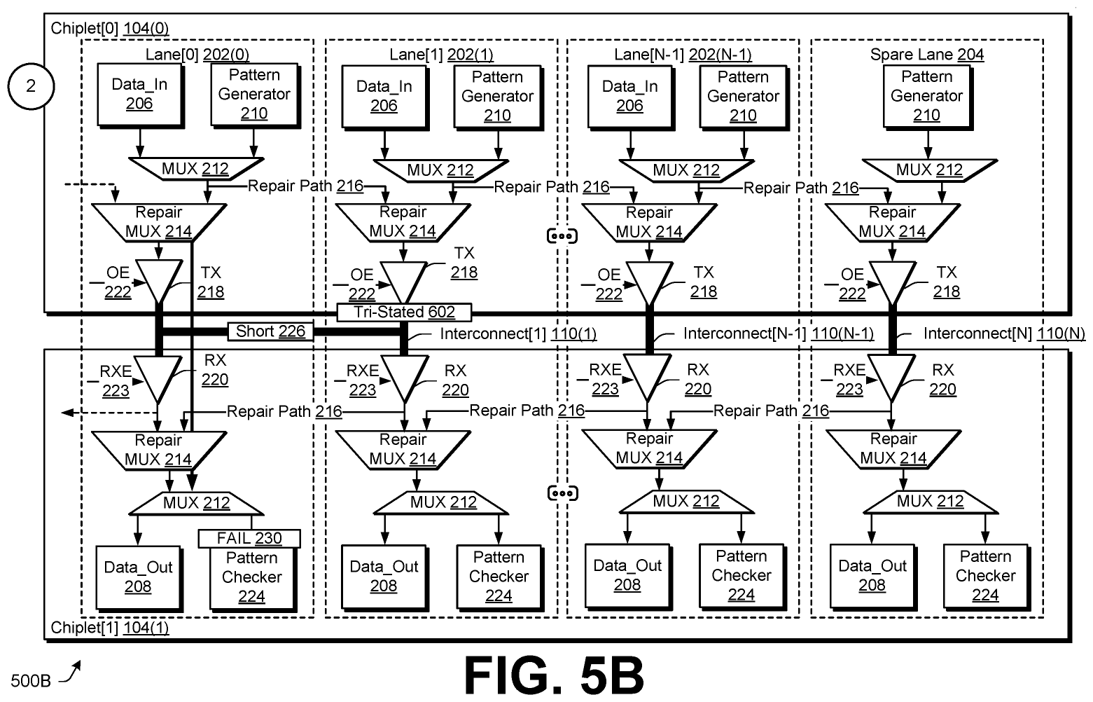

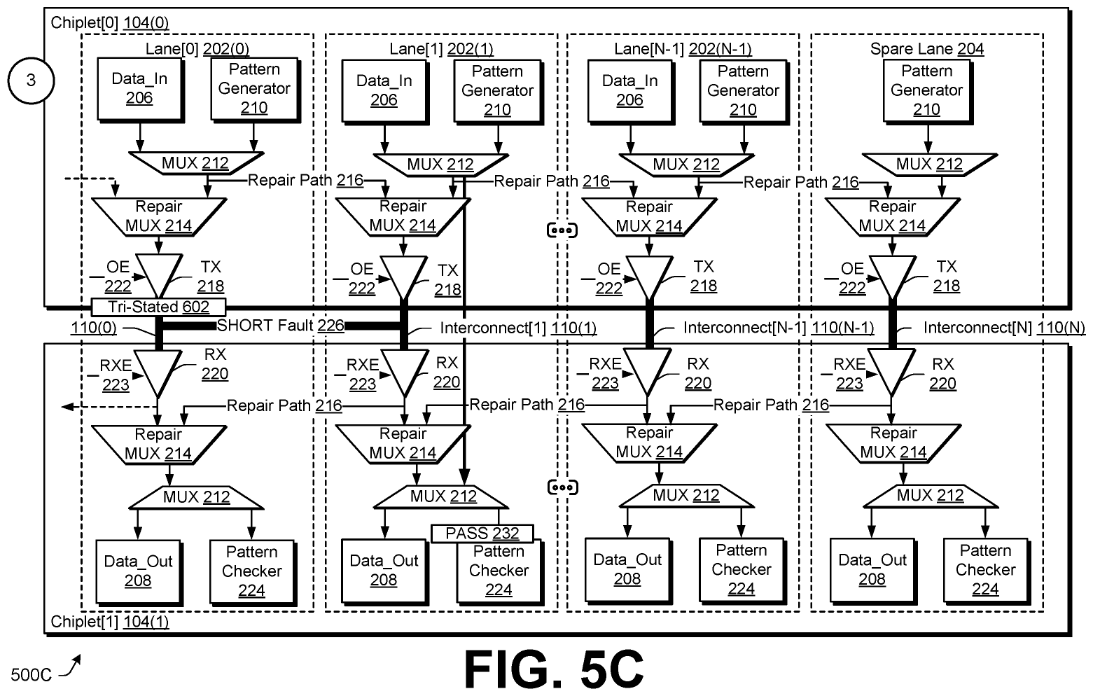

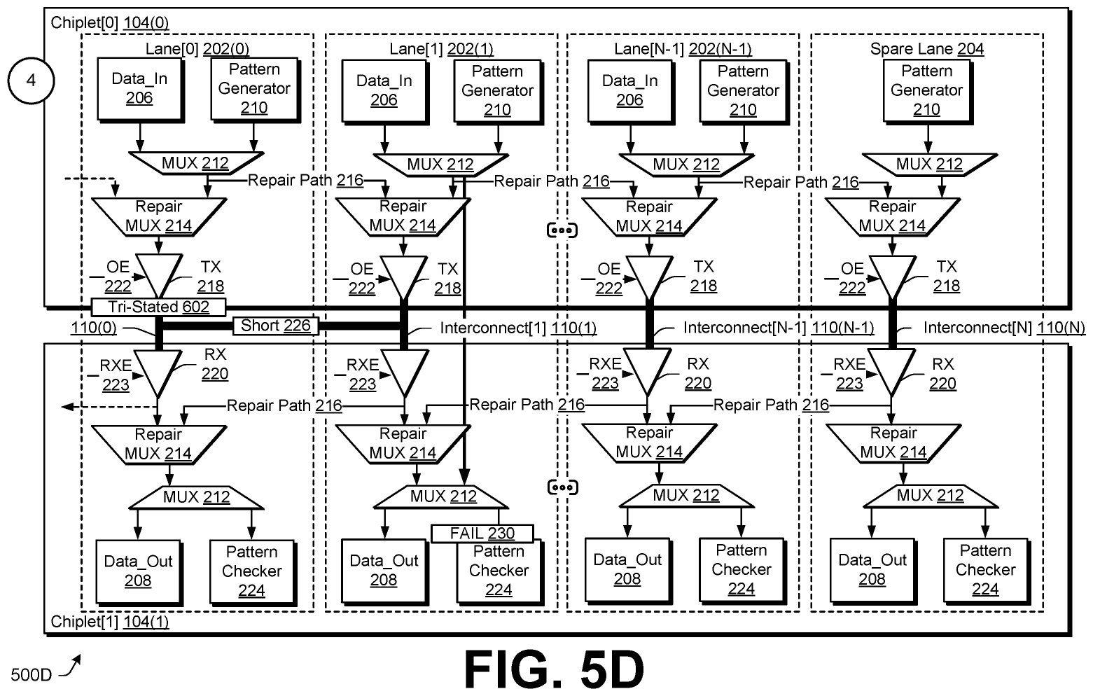

FIG. 4B depicts four scenarios labeled “1” through “4.” Each of these scenarios is representative of when adjacent lanes, such as lanes 202(0), 202(1), are shorted. Examples of scenarios “1” through “4” are depicted in FIG. 5A-5D, respectively.

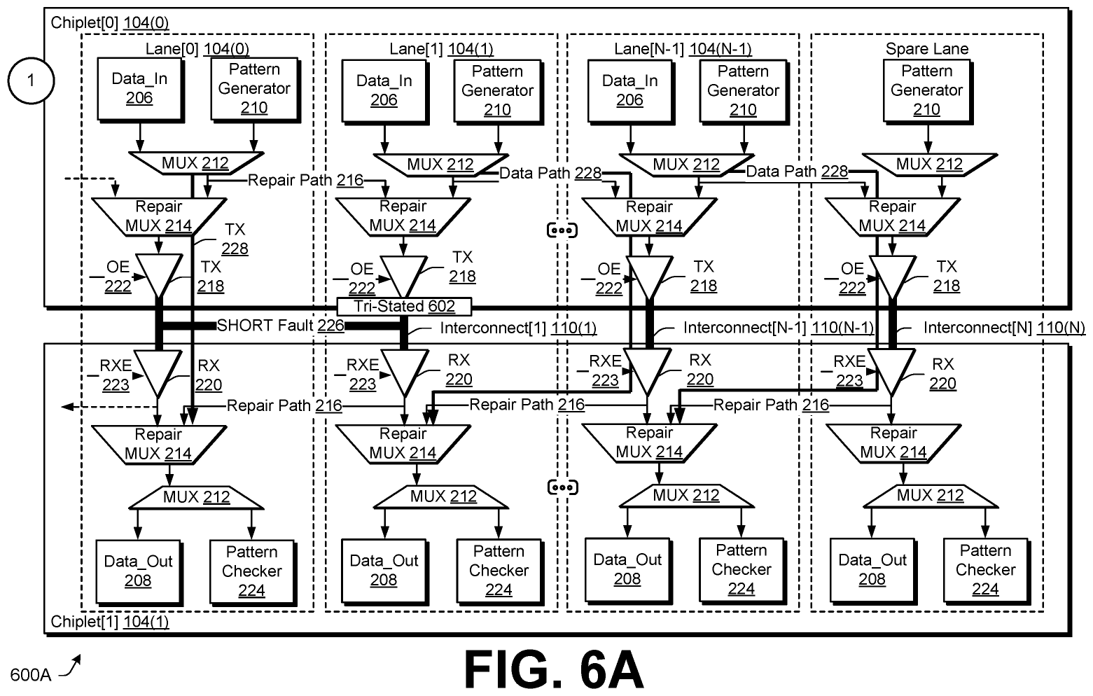

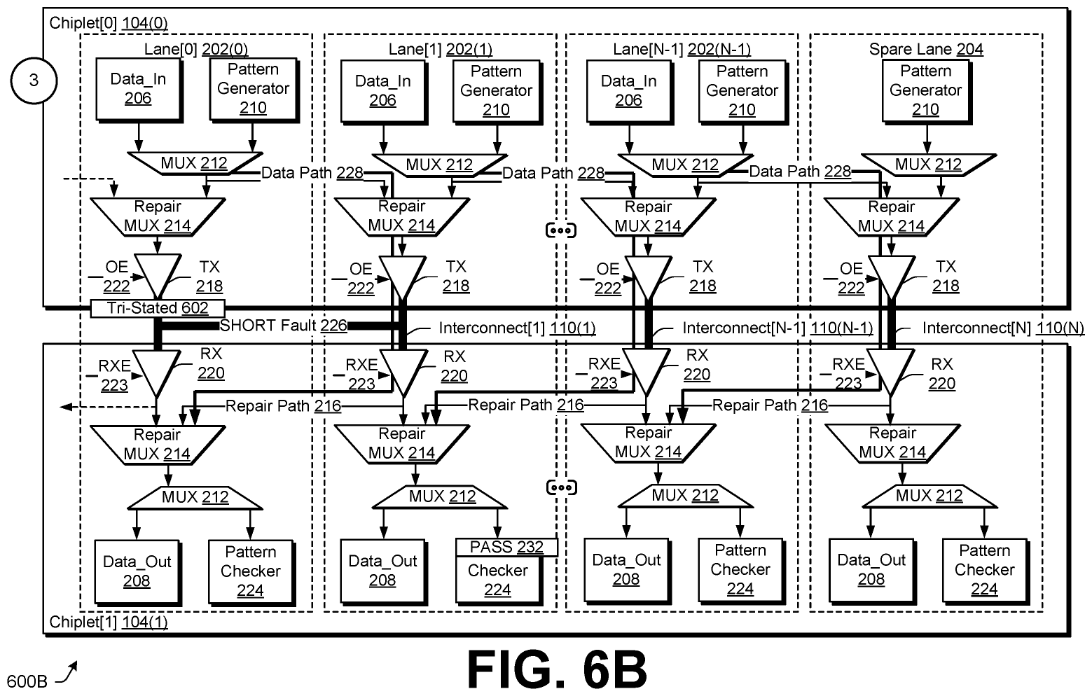

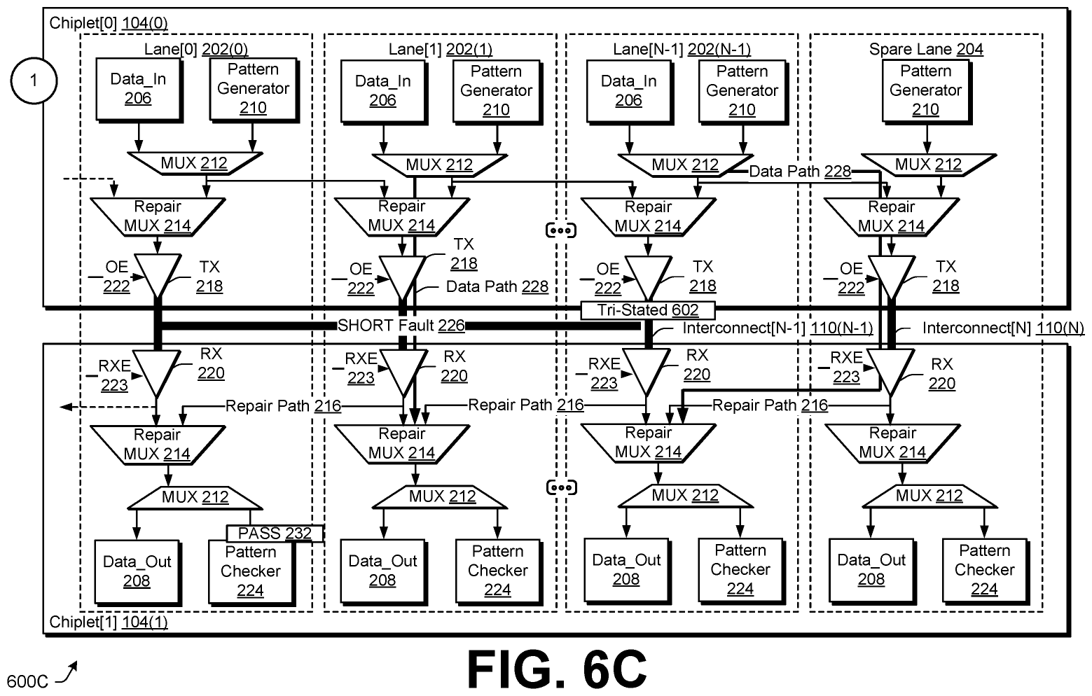

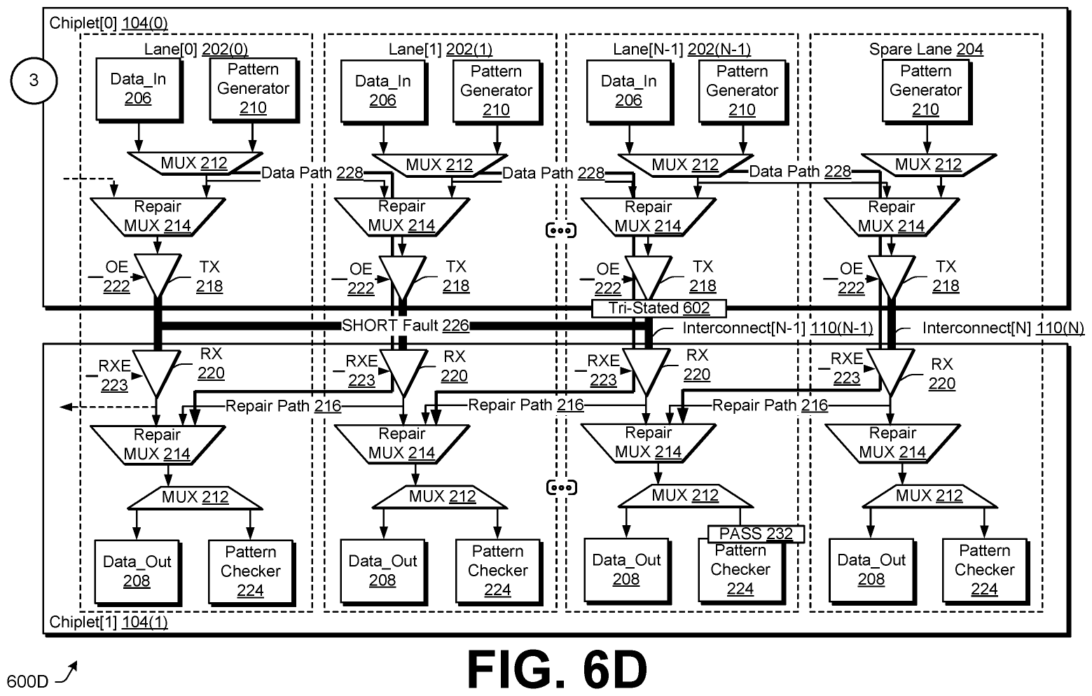

Scenario one is depicted in FIG. 5A and is representative of the case in which a non-limiting example self-repairable chip 500A exhibits only one checker failure for lane [0] 202(0) before the repair MUX 214 is configured (i.e., an overall checker PASS 232), but the part is still considered “repairable.” FIG. 6A depicts a non-limiting example self-repairable chip 600A in scenario one after the repair MUX 214 is configured and the transmitter macro 218 of lane [1] 202(1) is tri-stated 602, causing the data path 228 to be shifted to the right enabling the spare lane 204 to replace the lane [1] 202(1).

Scenario two is depicted in FIG. 5B and is representative of the case in which a non-limiting example self-repairable chip 500B exhibits two checker failures that have occurred (i.e., an overall checker FAIL 230) and the transmitter macro 218 and the receiver macro 220 of lane [0] 202(0) have reached maximum values for drive strength and sampling, respectively, lending to the part being considered “not repairable.”

Scenario three is depicted in FIG. 5C and is representative of the case in which a non-limiting example self-repairable chip 500C exhibits only one checker failure that has occurred (i.e., an overall checker PASS 232), but the part is considered “repairable.” FIG. 6B depicts a non-limiting example self-repairable chip 600B in scenario three after the repair MUX 214 is configured and the transmitter macro 218 of lane [0] 202(0) is tri-stated 602, causing the data path 228 to be shifted, enabling the spare lane 204 to replace the lane [1] 202(1).

Scenario four is depicted in FIG. 5D and is representative of the case in which a non-limiting example self-repairable chip 500D has two lanes that have failed and both lanes have their respective drive strength and sampling maxed out, lending to the part being considered “not repairable” (see block 424 of FIG. 4B).

Scenarios one and three also occur when neighbor lanes are shorted. For example, lane 202(0) and lane 202(N-1) are shorted and are neighbors to lane [1] 202(1). FIG. 6C depicts a non-limiting example self-repairable chip 600C in scenario one when the transmitter macro 218 of lane [N-1] 202(N-1) is tri-stated 602. FIG. 6D depicts a non-limiting example self-repairable chip 600D in scenario three when the transmitter macro 218 of lane [0] 202(0) is tri-stated 602.

It should be understood that many variations are possible based on the disclosure herein. Although features and elements are described above in particular combinations, each feature or element is usable alone without the other features and elements or in various combinations with or without other features and elements.

The various functional units illustrated in the figures and/or described herein, including, where appropriate, the SoC 102, the chiplets 104, the interposer 106, the package 108, the interconnects 110, the pins 112, the lanes 202, the pattern generators 210, the MUX 212, the repair MUX 214, the transmitter macros 218, the receiver macros 220, the pattern checkers 224, the drive strength control mechanisms 302, the PDLYs 308, or any combination thereof, are implemented in any of a variety of different manners such as subsystem circuitry, software or firmware executing on a programmable processor, or any combination of two or more of hardware, software, and firmware. The methods provided are implemented in any of a variety of devices, such as a general-purpose computer, a processor, or a processor core. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

In one or more implementations, the methods and procedures provided herein are implemented in a computer program, software, or firmware incorporated in a non-transitory computer-readable storage medium for execution by a general-purpose computer or a processor. Examples of non-transitory computer-readable storage mediums include a read only memory (ROM), a random-access memory (RAM), a register, cache memory, semiconductor memory devices, magnetic media such as internal hard disks and removable disks, magneto-optical media, and optical media such as CD-ROM disks, and digital versatile disks (DVDs).

Although the systems and techniques have been described in language specific to structural features and/or methodological acts, it is to be understood that the systems and techniques defined in the appended claims are not necessarily limited to the specific features or acts described. Rather, the specific features and acts are disclosed as example forms of implementing the claimed subject matter.

What is claimed is:

1. A system comprising:
a first chiplet connected to a second chiplet via a plurality of interconnects; and
one or more repair multiplexers configured to selectively enable a repair path responsive to a short fault between two interconnects of the plurality of interconnects based on a checked test pattern.

2. The system of claim 1, wherein a test pattern is generated on behalf of the first chiplet, and wherein the test pattern is checked on behalf of the second chiplet.

3. The system of claim 2, wherein the second chiplet is configured to indicate a checker fail responsive to the test pattern being different from the test pattern generated on behalf of the first chiplet.

4. The system of claim 3, wherein the checker fail occurs after one repair of an additional short fault between the two interconnects of the plurality of interconnects.

5. The system of claim 1, further comprising:
an interposer including the plurality of interconnects connecting a plurality of chiplets including the first chiplet and the second chiplet; and
a package including the plurality of chiplets, and the interposer.

6. A chiplet comprising:
a transmitter macro circuit configured to transmit a first test pattern to an additional chiplet during a self-test;
a receiver macro circuit configured to receive a second test pattern from the additional chiplet during the self-test;
a drive strength control mechanism configured to control a drive strength value of the transmitter macro circuit during transmission of the first test pattern to the additional chiplet to compensate for an additional load created by a short fault between the chiplet and the additional chiplet; and
a programmable delay mechanism configured to adjust a sampling window of the receiver macro circuit during reception of the second test pattern from the additional chiplet, the second test pattern interpreted as received to indicate a viability of using a repair path to bypass the short fault between the chiplet and the additional chiplet.

7. The chiplet of claim 6, further comprising a plurality of interconnects connecting the chiplet to the additional chiplet; and wherein the transmitter macro circuit is connected to a further receiver macro circuit of the additional chiplet via an interconnect of the plurality of interconnects.

8. The chiplet of claim 7, wherein the short fault is caused by the interconnect being shorted with an additional interconnect of the plurality of interconnects.

9. The chiplet of claim 8, wherein the transmitter macro circuit is configured to receive an output enable signal responsive to the interconnect being shorted with the additional interconnect of the plurality of interconnects.

10. The chiplet of claim 9, wherein:
responsive to the output enable signal being set to one, the drive strength control mechanism is configured to set the drive strength value to a minimum value; or
responsive to the output enable signal being set to zero, the transmitter macro circuit is configured to be tri-stated to disable output from the transmitter macro circuit.

11. A method comprising:
responsive to detecting two failing lanes between a first chiplet and a second chiplet of a chip as a result of a short fault, deactivating a transmitter macro circuit of a first failing lane of the two failing lanes to isolate a second failing lane of the two failing lanes;
reducing a drive strength of a transmitter macro circuit of the second failing lane, the reduced drive strength used to transmit a signal including a test pattern to a receiver macro circuit of the second failing lane;
adjusting a sampling window of the receiver macro circuit of the second failing lane, the adjusted sampling window used to receive the transmitted signal; and
executing a sub-routine to determine whether the test pattern is received correctly in the adjusted sampling window by the receiver macro circuit of the second failing lane, an output of the sub-routine indicating whether or not the chip is repairable based on a number of times the test pattern is received correctly.

12. The method of claim 11, wherein the short fault is between a first interconnect in the first failing lane and a second interconnect in the second failing lane.

13. The method of claim 12, wherein the first failing lane and the second failing lane are adjacent to each other.

14. The method of claim 12, wherein the first failing lane and the second failing lane are neighboring a third lane.

15. The method of claim 11, wherein the chip includes a system-on-a-chip.

16. The method of claim 11, wherein executing the sub-routine comprises:
incrementing the sampling window of the second receiver macro circuit of the second failing lane;
incrementing the drive strength of the second transmitter macro circuit of the second failing lane; and
transmitting, by the second transmitter macro circuit, for a number of cycles, a pattern generated by the first chiplet to the second chiplet.

17. The method of claim 16, wherein executing the sub-routine further comprises, responsive to the second chiplet identifying one checker failure, providing the output indicating that the chip is repairable.

18. The method of claim 16, wherein executing the sub-routine further includes, responsive to the second chiplet identifying two checker failures, maximizing the drive strength of the second transmitter macro circuit, and maximizing the sampling window of the second receiver macro:
deactivating the second transmitter macro of the second failing lane of the two failing lanes;
minimizing a drive strength value of the first transmitter macro of the first failing lane of the two failing lanes;
adjusting a sampling window of a first receiver macro of the first failing lane; and
re-executing the sub-routine, the output of which indicates whether or not the chip is repairable.

19. The method of claim 18, wherein, responsive to the output of re-executing the sub-routine indicating one checker failure, providing the output indicating that the chip is repairable.

20. The method of claim 18, wherein, responsive to the output of re-executing the sub-routine identifying two checker failures, maximizing the drive strength value of the first transmitter macro circuit, and maximizing the sampling window of the first receiver macro circuit, providing the output indicating that the chip is not repairable.
